(19) United States
(12) Patent Application Publication
(10) Pub. No.: US 2016/0211292 A1
(43) Pub. Date: Jul. 21, 2016

(54) METHOD FOR MANUFACTURING IMAGE PICKUP APPARATUS, AND IMAGE PICKUP APPARATUS

(71) Applicant: CANON KABUSHIKI KAISHA, Tokyo (JP)

(72) Inventors: Shinichiro Shimizu, Tokyo (JP); Hideaki Takada, Yokohama-shi (JP); Yasuharu Ota, Kawasaki-shi (JP); Takehiko Soda, Yokohama-shi (JP)

(21) Appl. No.: 14/992,243

(22) Filed: Jan. 11, 2016

(30) Foreign Application Priority Data
Jan. 15, 2015 (JP) 2015-006070

(51) Int. Cl. H01L 27/146; H01L 21/266

(52) U.S. Cl. CPC H01L 27/14612; H01L 27/1463; H01L 27/14643; H01L 27/14689; H01L 21/266

(57) ABSTRACT

A method for manufacturing an image pickup apparatus in which a second semiconductor region of first conductive type which becomes a well contact region is disposed adjacent to a first semiconductor region via an element isolation region in a pixel which has a well contact region among a plurality of pixels. A first mask which has openings in a region which becomes a first semiconductor region, an element isolation region disposed between the region which becomes the first semiconductor region and a region which becomes a second semiconductor region, and a region which becomes the second semiconductor region is disposed, and the first semiconductor region is formed in the region which becomes the first semiconductor region by conducting ion implantation of second conductive type at an oblique angle to a normal line of a principal surface using the first mask.

### BACKGROUND OF THE INVENTION

1. Field of the Invention

The present invention relates to a method for manufacturing an image pickup apparatus, and to a method for manufacturing a semiconductor region for supplying a predetermined voltage to a well in which an amplifying transistor of a pixel is disposed.

2. Description of the Related Art

A configuration in which a semiconductor region connected to an electric conductor to which a predetermined voltage is supplied is disposed in a well in which a source region and a drain region of an amplifying transistor of each pixel are arranged has been proposed (hereafter, a “well contact region”).

Japanese Patent Laid-Open No. 2011-071347 discloses an image pickup apparatus in which floating diffusion (hereafter, “FD”) to which charge of a photoelectric conversion unit is transferred and a well contact region are disposed adjacent to each other. The well contact region is disposed in each of a plurality of pixels. The well contact region is of conductivity type opposite to those of the source region and the drain region of the transistor of the pixel. Therefore, the well contact region, and the source region and the drain region of the transistor of the pixel are manufactured in different processes.

Japanese Patent Laid-Open No. 2011-251800 discloses a method for forming a source region and a drain region of the transistor of a pixel by ion implantation using a gate electrode as a mask (hereafter, “self-alignment formation). Japanese Patent Laid-Open No. 2011-251800 discloses a method for forming a source region and a drain region by self-alignment formation by forming FD by ion implantation at an oblique angle to a normal line of a principal surface of a semiconductor substrate.

### SUMMARY OF THE INVENTION

The present disclosure is a method for manufacturing an image pickup apparatus which includes a plurality of pixels, each of which has a photoelectric conversion unit, floating diffusion which holds charge generated in the photoelectric conversion unit, an amplifying transistor electrically connected to the floating diffusion, and a reset transistor which resets a potential of an input node of the amplifying transistor, wherein some of the plurality of pixels have a well contact region connected to a conductor which supplies a predetermined voltage to the well and others do not, each of the plurality of pixels has a first semiconductor region of a second conductive type which constitutes a source region of the reset transistor and the floating diffusion in the well of the first conductivity type, and an element isolation region is disposed on a principal surface of a semiconductor substrate, and a second semiconductor region of a first conductive type which becomes the well contact region is disposed at a position adjacent to the first semiconductor region via the element isolation region in a pixel which has the well contact region, the method including: a first process in which a first mask having openings in a region which becomes the first semiconductor region, the element isolation region disposed between a region which becomes the first semiconductor region and a region which becomes the second semiconductor region, and the region which becomes the second semiconductor region is disposed, and ion implantation of a second conductive type is conducted at an oblique angle to a normal line of the principal surface using the first mask to form the first semiconductor region in the region which becomes the first semiconductor region; and a second process in which a second mask which covers the region which becomes the first semiconductor region and has an opening in the region which becomes the second semiconductor region is disposed, and the second semiconductor region is formed in the region which becomes the second semiconductor region by conducting ion implantation of the first conductive type using the second mask.

Further features of the present invention will become apparent from the following description of exemplary embodiments with reference to the attached drawings.

### BRIEF DESCRIPTION OF THE DRAWINGS

FIG. 1 is a block diagram of an image pickup apparatus applicable to the present invention.

FIG. 2 is a circuit diagram of a pixel applicable to the present invention.

FIGS. 3A and 3B are top views of a pixel according to a first embodiment.

FIG. 4 is a top view of a pixel unit according to the first embodiment.

FIGS. 5A and 5B are cross-sectional views of the pixel unit according to the first embodiment.

FIGS. 6A to 6C are explanatory views of a manufacturing process of the pixel unit according to the first embodiment.

FIGS. 7A to 7C are explanatory views of a manufacturing process of the pixel unit according to the first embodiment.

FIGS. 8A to 8C are explanatory views of a manufacturing process of the pixel unit according to the first embodiment.

FIGS. 9A to 9C are explanatory views of a manufacturing process of the pixel unit according to the first embodiment.

FIGS. 10A to 10C are explanatory views of a manufacturing process of the pixel unit according to the first embodiment.

FIG. 11 is a top view of a pixel unit according to a second embodiment.

FIGS. 12A and 12B are explanatory views of a manufacturing process of the pixel unit according to the second embodiment.

FIG. 13 is a top view of the pixel unit according to the second embodiment.

### DESCRIPTION OF THE EMBODIMENTS

Hereinafter, an image pickup apparatus according to embodiments of the present invention are described with reference to the drawings. In the drawings, the same elements having the same function are denoted by the same reference numerals and duplicate explanation is omitted.

### First Embodiment

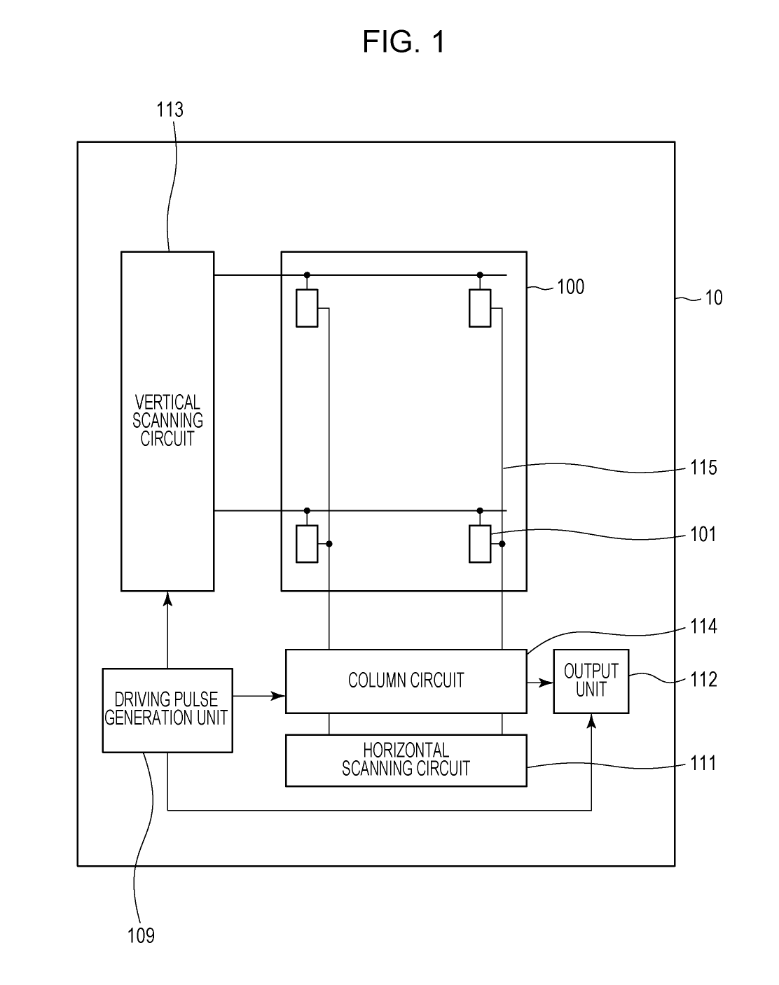

An image pickup apparatus 10 of the present embodiment is described with reference to FIGS. 1 to 5B.

FIG. 1 is a block diagram of the image pickup apparatus 10 according to the present embodiment. The image pickup apparatus 10 includes a pixel unit 100, a driving pulse generation unit 109, a vertical scanning circuit 113, a signal line 115, a column circuit 114, a horizontal scanning circuit 111, and an output unit 112.

The pixel unit 100 includes a plurality of pixels 101 that convert light into charge signals and output the converted charge signal. The plurality of pixels 101 are arranged in a matrix form.

The driving pulse generation unit 109 generates driving pulses. The vertical scanning circuit 113 receives the driving pulses from the driving pulse generation unit 109 and supplies control pulses to each pixel column. The control pulses supplied here are pTX that drives a transfer transistor, pRES that drives a reset transistor, and pSEL that drives a selection transistor which are described later. The column circuit 114 processes in parallel signals output from the pixel unit 100. The column circuit 114 includes an amplifier unit, a noise reduction unit, and an AD conversion unit. The horizontal scanning circuit 111 outputs signals processed by the column circuit 114 to the output unit 112 for each column.

The driving pulse generation unit 109, the vertical scanning circuit 113, the column circuit 114, the horizontal scanning circuit 111, and the output unit 112 constitute a peripheral circuit arranged around the pixel unit 100, and a region where these components are arranged is referred to as a peripheral circuit region. The AD conversion unit is included in the column circuit 114 here, but this configuration is not restrictive.

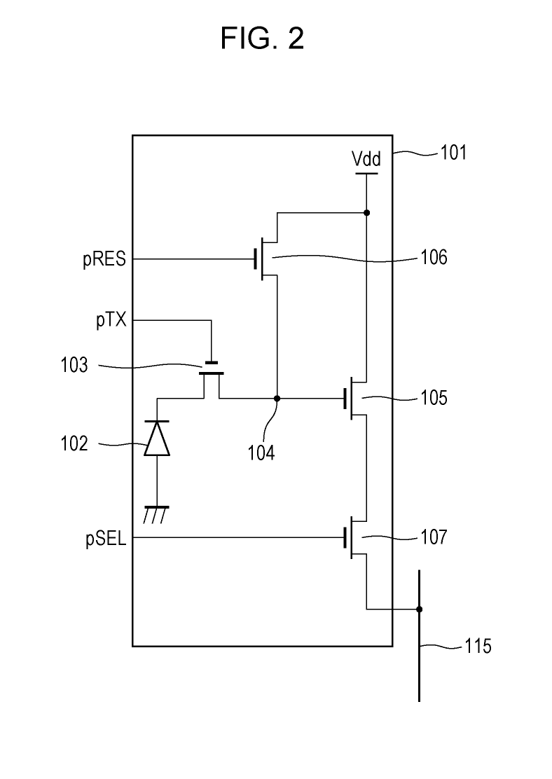

FIG. 2 illustrates an exemplary equivalent circuit of a single pixel. In the present embodiment, signal charge is described as an electron and each transistor is described as an N-type transistor. Alternatively, a hole may be used as the signal charge and a P-type transistor may be used as the transistor of the pixel. In the present embodiment, a semiconductor region of a first conductive type is P-type, and a semiconductor region of a second conductive type is N-type.

An equivalent circuit is not limited to that described above, and a part of the configuration may be shared by a plurality of pixels. The same applies to the following embodiments.

The pixel 101 includes a photoelectric conversion unit 102, a transfer transistor 103, a reset transistor 106, an amplifying transistor 105, floating diffusion (hereafter, “FD”) 104, and a selection transistor 107.

The photoelectric conversion unit 102 produces a charge pair of a quantity according to incident light quantity by photoelectric conversion, and accumulates electrons. The photoelectric conversion unit 102 is formed, for example, by photodiode.

The transfer transistor 103 transmits electrons accumulated by the photoelectric conversion unit 102 to the FD 104. The control pulse pTX is supplied to a gate of the transfer transistor 103 to switch between an ON state and an OFF state. The FD 104 holds electrons transmitted by the transfer transistor 103.

The amplifying transistor 105 is connected to the FD 104 at a gate thereof, and outputs amplified signals based on the electrons transmitted to the FD 104 by the transfer transistor 103. Specifically, the electrons transmitted to the FD 104 are converted into a voltage according to the quantity thereof, and charge signals according to the voltage are output to the signal line 115 via the amplifying transistor 105.

The amplifying transistor 105 constitutes a source follower circuit together with an unillustrated current source. In this circuit, an input node of the amplifying transistor 105 includes the FD 104, a source region of the reset transistor 106, a gate of the amplifying transistor 105, and an electric conductor which electrically connects these components.

The reset transistor 106 resets a potential of the input node of the amplifying transistor 105. A potential of the photoelectric conversion unit 102 is reset when the ON state of the reset transistor 106 and the ON state of the transfer transistor 103 are superimposed. The control pulse pRES is supplied to the gate of the reset transistor 106 to switch between the ON state and the OFF state.

The selection transistor 107 makes signals of a plurality of pixels provided on a single signal line 115 output from each one pixel or each of a plurality of pixels at a time. The drain of the selection transistor 107 is connected to the source of the amplifying transistor 105, and the source of the selection transistor 107 is connected to the signal line 115.

Alternatively, the selection transistor 107 may be provided between the drain of the amplifying transistor 105 and a power supply line to which a power supply voltage is supplied. In any of these cases, the selection transistor 107 controls electrical connection of the amplifying transistor 105 and the signal line 115. The control pulse pSEL is supplied to the gate of the selection transistor 107 to switch between the ON state and the OFF state of the selection transistor 107.

Alternatively, instead of providing the selection transistor 107, a selected state and a non-selected state may be switched by connecting the source of the amplifying transistor 105 to the signal line 115 and switching a potential of the drain of the amplifying transistor 105 or the gate of the amplifying transistor 105.

An equivalent circuit is not limited to that described above, and a part of the configuration may be shared by a plurality of pixels. The present embodiment is applicable to both an image pickup apparatus of front-side irradiation type in which light enters from a front side, and an image pickup apparatus of back-side irradiation type in which light enters from a back side. The same applies to the following embodiments.

A plurality of pixels arranged in the pixel unit 100 of the image pickup apparatus 10 of the present embodiment are disposed in an unillustrated well of first conductivity type. Some pixels among a plurality of pixels are provided with a well contact region which provides a reference potential to the wells.

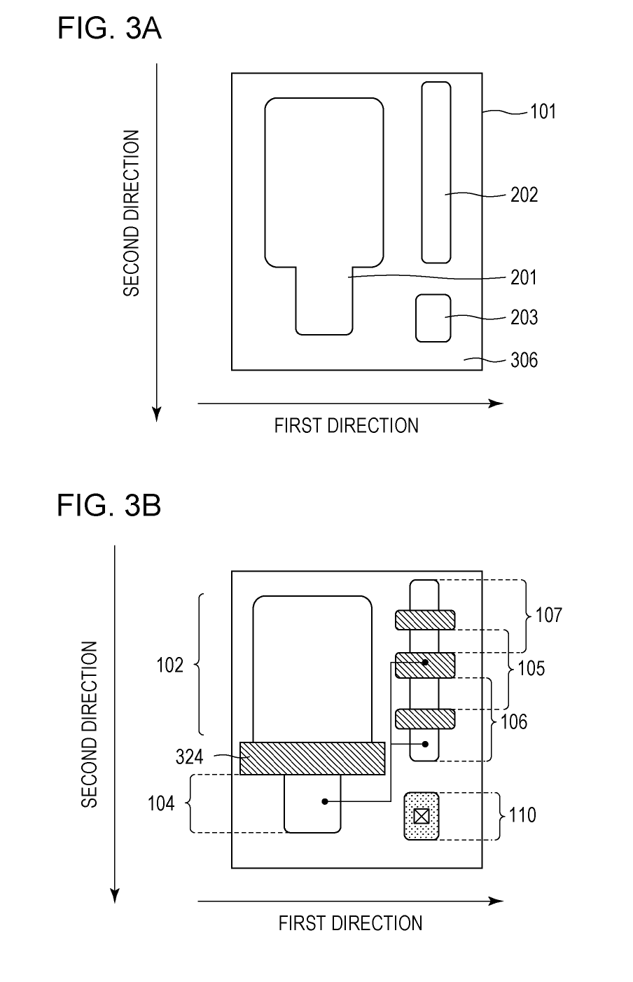

FIG. 3A illustrates an element isolation region 306 and active regions 201 to 203 separated by the element isolation region 306. The element isolation region 306 is disposed to separate the active region 201 from peripheral elements or peripheral active regions. The element isolation region 306 may be formed, for example, by an insulator isolation portion formed by a LOCOS process and an STI separation unit. The element isolation region 306 may be a high-concentration P-type semiconductor region. Hereinafter, description is made in which the insulator isolation portion formed by the LOCOS process is used as the element isolation region.

FIG. 3B illustrates a state where a gate electrode is disposed on each active region of FIG. 3A. The reference numerals of the active regions (201 to 203) in FIG. 3A are omitted in FIG. 3B. The photoelectric conversion unit 102 and the FD 104 are disposed in the active region 201. Each of the source regions and the drain regions of the amplifying transistor 105, the reset transistor 106, and the selection transistor 107 are disposed in the active region 202. The well contact region 110 is disposed in the active region 203.

The active region 201 and the active region 202 are arranged in a first direction. The active region 202 is elongated in a second direction different from the first direction (typically, a direction which crosses perpendicularly the first direction) when seen in a plan view. The active region 202 and the active region 203 are arranged in the second direction.

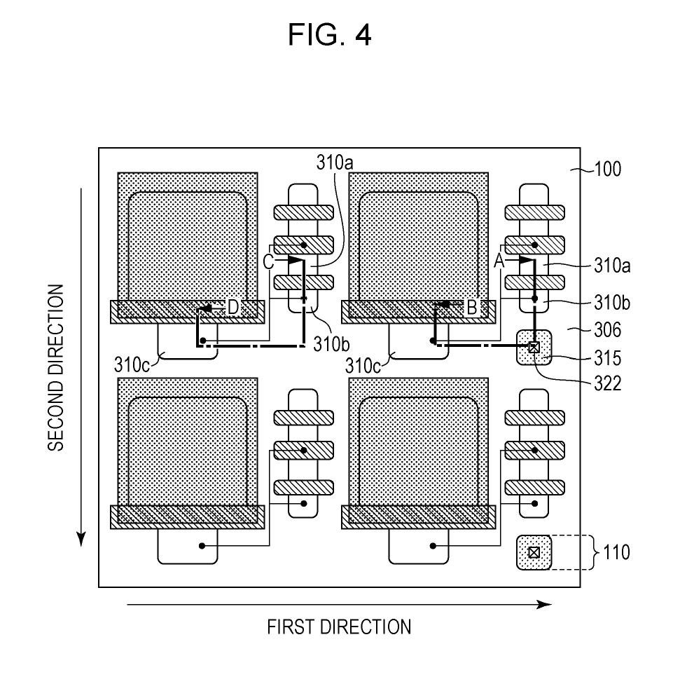

FIG. 4 is a schematic plan view of the pixel unit 100 in which a plurality of pixels 101 illustrated in FIG. 3B are arranged. Four (2×2) pixels are illustrated in FIG. 4. No well contact region 110 is provided for the left two pixels whereas a well contact region 110 is provided for each of the right two pixels. In the configuration illustrated in FIG. 4, the well contact region 110 is provided every two pixels.

In the present embodiment, a mask having openings above the source region of the reset transistor 106, the FD 104, the element isolation region disposed between the source region of the reset transistor 106 and the well contact region 110, the element isolation region disposed between the FD 104 and the well contact region 110, and the well contact region 110 is used. As an example, description is made with reference to a mask which covers a region that becomes the photoelectric conversion unit 102 and has openings in other regions. Impurity ions implantation is conducted to the FD 104 of the active region 201, and the source region and the drain region of each transistor of the active region 202 using the mask.

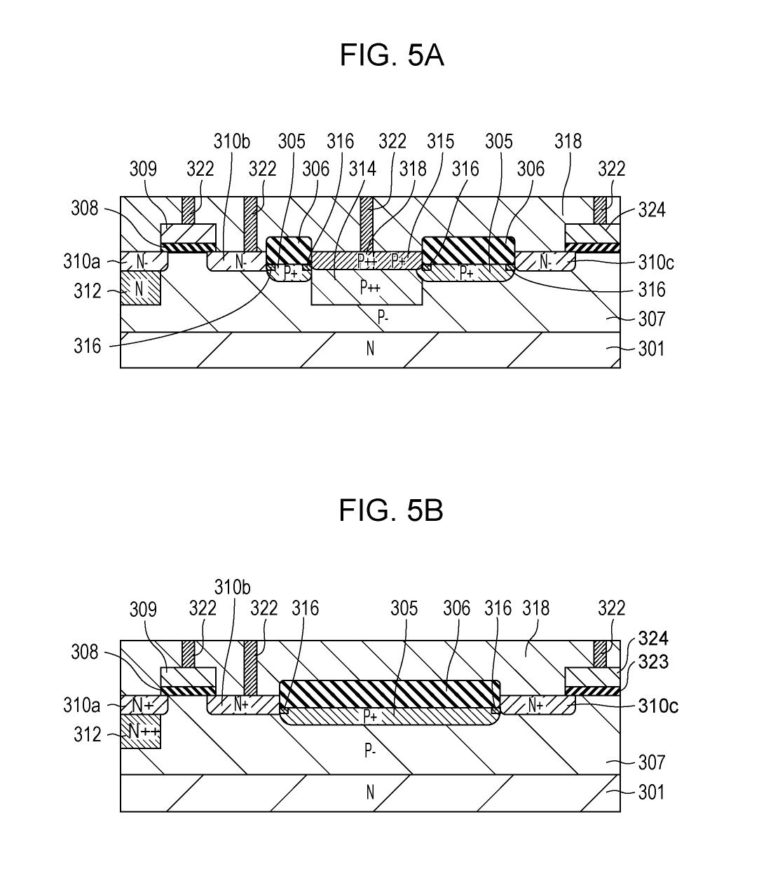

FIG. 5A is a cross-sectional view along line A-B of FIG. 4, and FIG. 5B is a cross-sectional view along line C-D of FIG. 4.

Although not illustrated, a plurality of pixels are arranged in a P-type well 307 in FIG. 5A. In the pixel 101, the semiconductor regions which constitute the source region and the drain region of each transistor and the well contact region 110 are disposed in the well. A P-type semiconductor region 305 with high impurity concentration is disposed below the element isolation region 306 as a channel stop region. The P-type semiconductor region, constituted by P-type semiconductor regions 314, 315 and 318, is disposed in the well contact region 110.

The P-type semiconductor region disposed in the well contact region 110 is connected to a contact plug 322 to which a predetermined voltage is supplied, and supplies a predetermined voltage to the well 307. The voltage supplied to the well 307 is, for example, a ground voltage. A P-type semiconductor region 316 with impurity concentration lower than those of the P-type semiconductor regions 314 and 315 is disposed between the P-type semiconductor region 305 below the element isolation region 306 and the P-type semiconductor region 315.

An N-type semiconductor region 310b (“first semiconductor region”) is disposed in one of the regions adjacent to the well contact region 110 via the element isolation region 306. The N-type semiconductor region 310b constitutes the source region of the reset transistor 106 and constitutes a part of the input node of the amplifying transistor 105. An N-type semiconductor region 310a and an N-type semiconductor region 312 constitute a drain region of the reset transistor 106, and a gate electrode 309 constitutes the gate electrode of the reset transistor 106.

An N-type semiconductor region 310c (“first semiconductor region”) is disposed in the other of the regions adjacent to the well contact region 110 via the element isolation region 306. The N-type semiconductor region 310c constitutes the FD 104 and constitutes a part of the input node of the amplifying transistor 105. The FD 104 also constitutes a drain region of the transfer transistor 103, and a gate electrode 324 constitutes the gate electrode of the transfer transistor 103.

FIG. 5B illustrates a cross section of a pixel 101 where no well contact region 110 is disposed. The element isolation region 306 is disposed in the region corresponding to the region in which the well contact region 110 is disposed in FIG. 5A. Other configurations are the same as that of FIG. 5A.

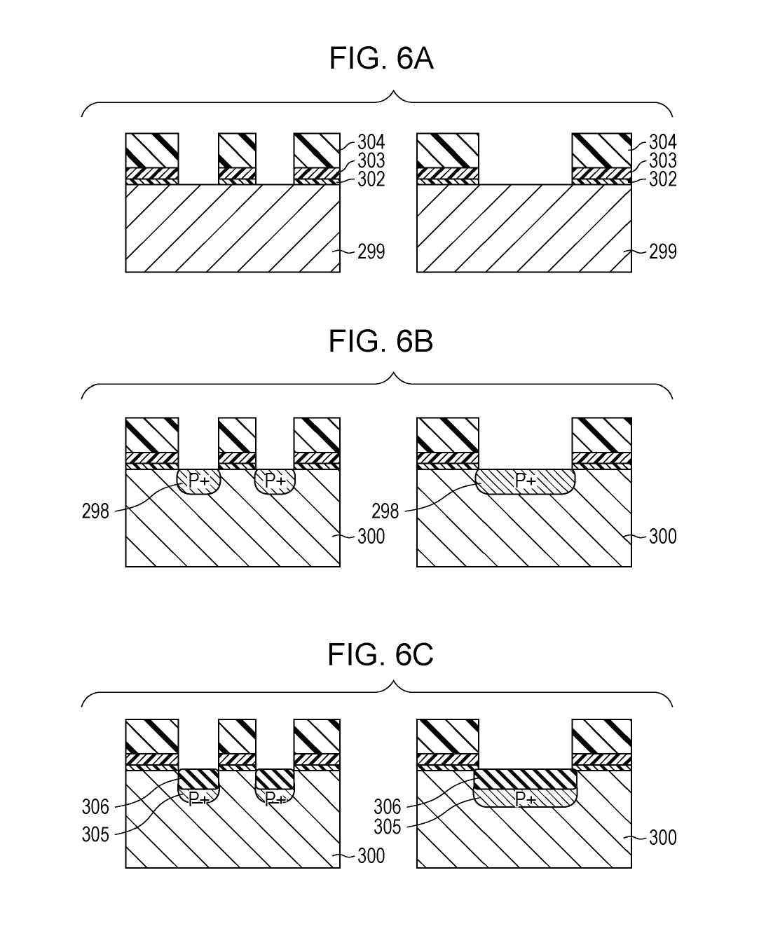

Next, a process of manufacturing the image pickup apparatus in the cross section of FIGS. 5A and 5B is described with reference to FIGS. 6A to 6C. The order of the process steps may be changed unless otherwise specified. Well-known manufacturing methods are applicable to the process steps which are not specified.

The left diagrams in FIGS. 6A to 6C illustrate processes of manufacturing a region along line A-B of FIG. 4, and the right diagrams of FIGS. 6A to 6C illustrate processes of manufacturing a region along line C-D of FIG. 4.

In FIG. 6A, a silicon oxide film 302, a polysilicon film 303, and a silicon nitride film 304 are formed in this order on a semiconductor substrate 299 to form a laminated film including these three films, and then a part of the laminated film is patterned. The portion from which the laminated film is removed by the patterning becomes the element isolation region 306 later. The conductivity type of the semiconductor substrate 299 may be N-type or P-type. The semiconductor substrate 299 may be a substrate with an epitaxial layer formed on a surface thereof.

In FIG. 6B, ion implantation is conducted in parallel with the normal line of a principal surface of the semiconductor substrate 299 of FIG. 6A. Specifically, using the laminated film as a mask, a P-type semiconductor region 298 is formed on the semiconductor substrate 299 by conducting P-type ion implantation at the opening formed by removing the laminated film (“intermediate B”). The P-type semiconductor region 298 becomes a part of the channel stop region later. The principal surface is a surface of the semiconductor substrate 299 on which the element isolation region is formed.

Next, in FIG. 6C, the element isolation region 306 is formed by the LOCOS process in which the semiconductor substrate 300 and the entire laminated film are heated (“intermediate C”). The region in which the element isolation region 306 is not formed becomes the active region.

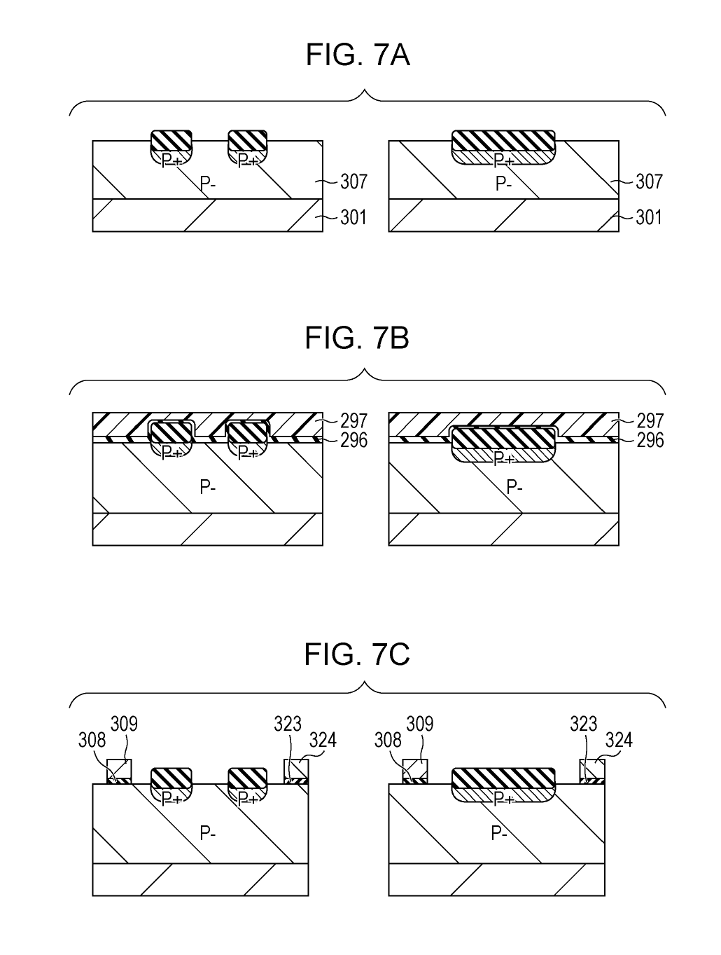

Next, as illustrated in FIG. 7A, impurity implantation is conducted to the entire pixel unit 100 of the semiconductor substrate 300 to obtain the semiconductor substrate 301 in which the P-type well 307 is formed (“intermediate D”). The P-type well 307 may be formed only in the pixel unit 100, or may be formed also in the peripheral circuit region disposed around the pixel unit 100.

If the P-type well 307 is formed only in the pixel unit 100, it is only necessary to conduct the ion implantation of FIG. 7A using the mask with the peripheral circuit region being shielded. In this case, the P-type well different from the P-type well 307 is formed in the peripheral circuit region by conducting ion implantation using the mask with the pixel unit 100 being shielded before or after the impurity implantation process of FIG. 7A. If the N-type well is needed in the peripheral circuit region, it is only necessary to conduct the N-type ion implantation at the peripheral circuit region to form the N-type well using a mask with the regions in which the pixel unit and the P-type well of the peripheral circuit region will be formed being shielded.

Next, as illustrated in FIG. 7B, an insulating film 296 is formed above the entire intermediate D. The insulating film 296 may be formed by various methods. The insulating film 296 may be desirably silicon oxide film or silicon nitride film, which can be formed by, for example, thermal oxidation and CVD. A polysilicon film 297 is formed on the insulating film 296 (“intermediate E”).

Next, as illustrated in FIG. 7C, the gate electrodes 309 and 324 and gate insulating films 308 and 323 are formed by removing a part of the region of the polysilicon film 297 of the intermediate E and the insulating film 296 by patterning. A part of the gate electrode 324 is not illustrated. The gate electrode 309 is disposed above a predetermined position of the active region and becomes the gate electrode of the reset transistor 106, and the gate electrode 324 becomes the gate electrode of the transfer transistor 103 (“intermediate F”).

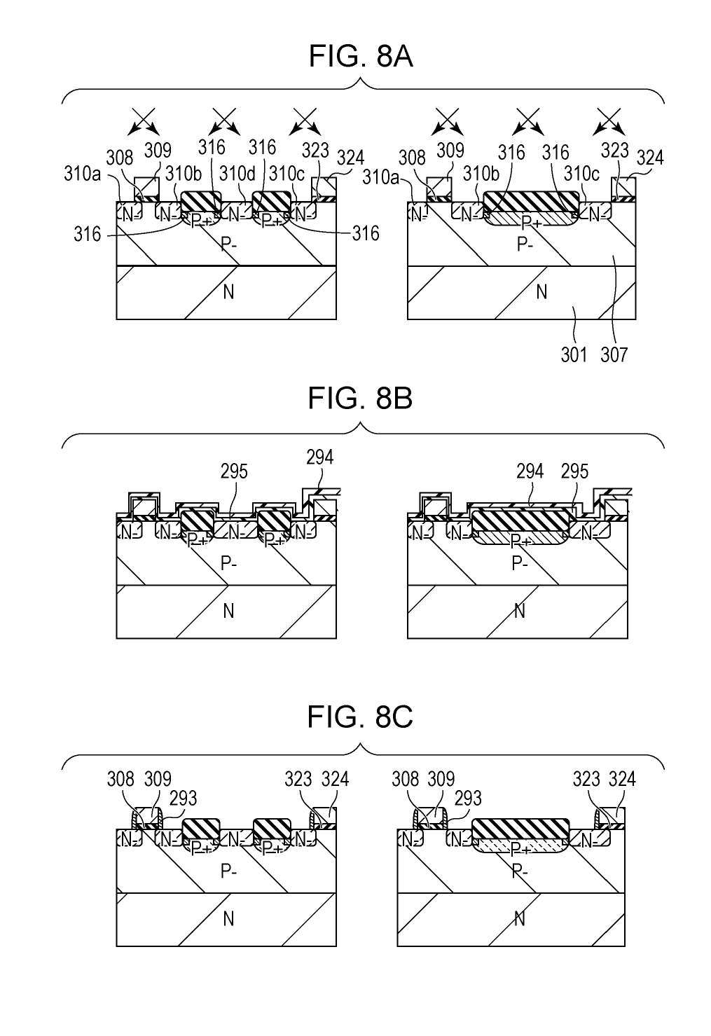

Next, as illustrated in FIG. 8A, ion implantation is conducted from an oblique angle to the normal line of the principal surface of the semiconductor substrate to the intermediate F using the gate electrodes 309 and 324 as the mask (“first process”). Specifically, rotational ion implantation is conducted at an angle inclined from 20 to 70 degrees to the normal line of the principal surface of the semiconductor substrate. The dosage at this time is 2.5×10¹² atoms/cm²≦D1≦2.5×10¹⁴ atoms/cm².

With this ion implantation, the N-type semiconductor regions 310a, 310b, 310c, and 310d are formed. The ion implantation is conducted in a state where the region which becomes the photoelectric conversion unit is shielded using a mask (“first mask”) formed by, for example, unillustrated photoresist.

The first mask may be disposed above the gate electrode 324. The first mask has an opening in a region which becomes the well contact region 110 in the pixel which has the well contact region 110. The first mask also has openings corresponding to the element isolation region 306 disposed between the region which becomes the FD 104 and the region which becomes the well contact region 110, and the element isolation region 306 disposed between the region which becomes the source of the reset transistor 106 and the region which becomes the well contact region 110. Also in a pixel which has no well contact region 110, the first mask has an opening at the same position as the pixel having a well contact region 110.

Therefore, a part of the region of the source region and the drain region of the reset transistor 106 and the FD 104 are formed by self-alignment formation. The N-type semiconductor region 310a constitutes a part of a low-concentration region of the drain region of the reset transistor 106, and the N-type semiconductor region 310b constitutes the source region of the reset transistor 106. The N-type semiconductor region 310c is the low-concentration N-type semiconductor region which becomes the FD. The N-type semiconductor region 310d is an N-type semiconductor region disposed in the region which becomes the well contact region 110. A part or the entire N-type semiconductor region 310d becomes the P-type semiconductor region in the subsequent process.

Since the ion implantation conducted in FIG. 8A is conducted as rotational ion implantation, a part of P-type impurity concentration in the P-type semiconductor region 305 disposed below the element isolation region 306 becomes low, and the P-type semiconductor region 316 is formed (“intermediate G”).

Next, as illustrated in FIG. 8B, the laminated film of the silicon nitride film 295 and the silicon oxide film 294 is formed above the entire principal surface in which a gate electrode of an intermediate G is formed. These films are formed by plasma CVD (“intermediate H”).

Next, as illustrated in FIG. 8C, side spacers 293 are formed on side surfaces of the gate electrode 309 and the gate electrode 324 by removing (i.e., etching) the laminated film of the silicon nitride film 295 and the silicon oxide film 294 of the intermediate H (“intermediate I”). A part of the side spacer 293 of the gate electrode 324 is not illustrated. The side spacers are formed also in other gate electrodes of transistors which are not illustrated.

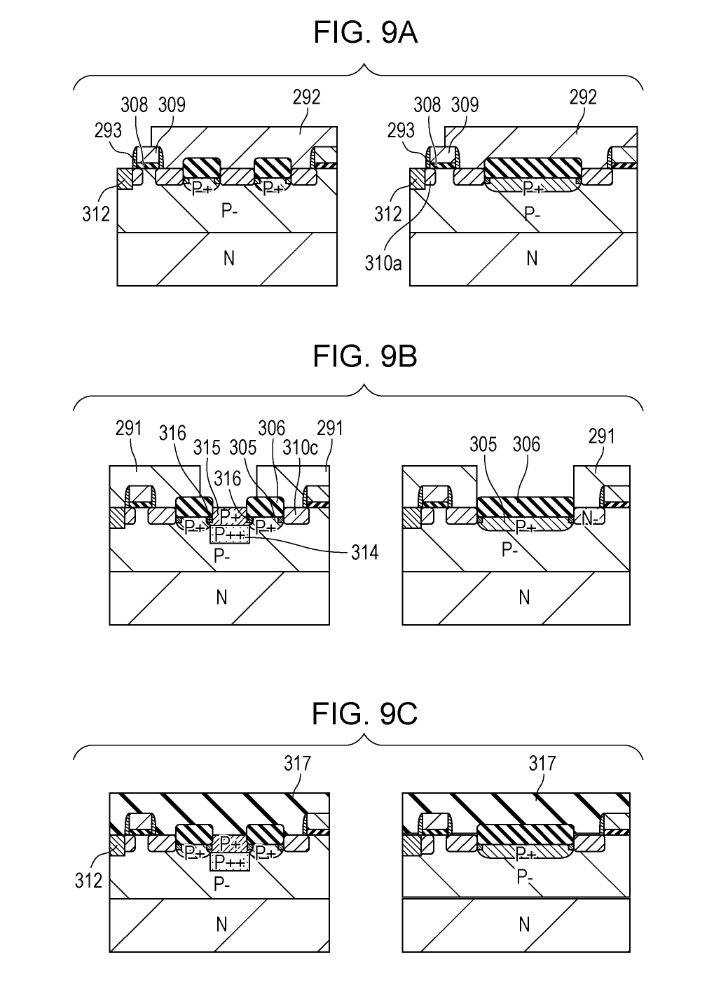

Next, a mask 292 is formed as illustrated in FIG. 9A. The mask 292 shields N-type semiconductor regions 310b, 310c and 310d, a region which becomes the well contact region 110, the photoelectric conversion unit 102, and the gate electrode 324 of the intermediate I.

The mask 292 has openings at portions corresponding to the source region and the drain region of other transistors (i.e., an amplifying transistor and a selection transistor) of the pixel.

Impurity implantation is conducted in parallel with the normal line of the principal surface of the semiconductor substrate using the mask 292. The N-type semiconductor region 312 is formed by self-alignment with respect to the side spacer 293 (“intermediate J”). Therefore, the source region and the drain region of other transistors of the pixel are formed.

Next, as illustrated in FIG. 9B, a mask 291 which covers regions except for the region which becomes the well contact region 110 and has an opening corresponding only to the region which becomes the well contact region 110 is formed (“second mask”), and P-type ion implantation is conducted (“second process”). The second mask may have an opening above the element isolation region 306.

The dosage may be determined under a condition with which the N-type semiconductor region 310d becomes the P-type semiconductor region and may be, for example, 4.0×10¹⁴ atoms/cm²≦D2 4.0¹⁶ atoms/cm². Therefore, a P-type semiconductor region (“second semiconductor region”) is formed in the region which becomes the well contact region 110. The second semiconductor region is constituted by the P-type semiconductor region 315 disposed on the front surface side of the semiconductor substrate 301, and the P-type semiconductor region 314 disposed at a deeper position of the semiconductor substrate than the P-type semiconductor region 315.

The P-type semiconductor region 315 is formed by conducting P-type ion implantation in the region where the N-type semiconductor region 310d disposed in the process of FIG. 8A exists.

The P-type semiconductor region 314 is formed by conducting P-type impurity ion implantation in the P-type well 307. Therefore, P-type impurity concentration in the P-type semiconductor region 314 is higher than in the P-type semiconductor region 315.

N-type impurity ions are implanted in a part of the portion below the element isolation region 306 in the impurity implantation process of FIG. 8A and the P-type semiconductor region 316 with low impurity concentration is disposed. The P-type ion implantation of this process is conducted in the direction of the normal line to the principal surface of the semiconductor substrate 301. Therefore, the P-type semiconductor region 316 with lower concentration than those of the P-type semiconductor regions 305 and 315 is disposed between the P-type semiconductor region 315 and the P-type semiconductor region 305 (“intermediate K”).

According to this configuration, an electric field at the end of the element isolation region 306 can be alleviated. With this configuration, generation of hot carrier amplification can be controlled and noise can be reduced.

In the process of FIG. 9B, impurity implantation may be conducted in parallel with the normal line of the principal surface of the semiconductor substrate, or may be conducted from an oblique angle to the normal line. However, if the impurity implantation is conducted from an oblique angle to the normal line, the P-type semiconductor region 316 is not formed.

Next, as illustrated in FIG. 9C, an interlayer insulation film 317 is formed on the principal surface of the semiconductor substrate 301 of the intermediate K. The interlayer insulation film 317 may be formed using, for example, a silicon oxide film, BPSG, and NSG (“intermediate L”).

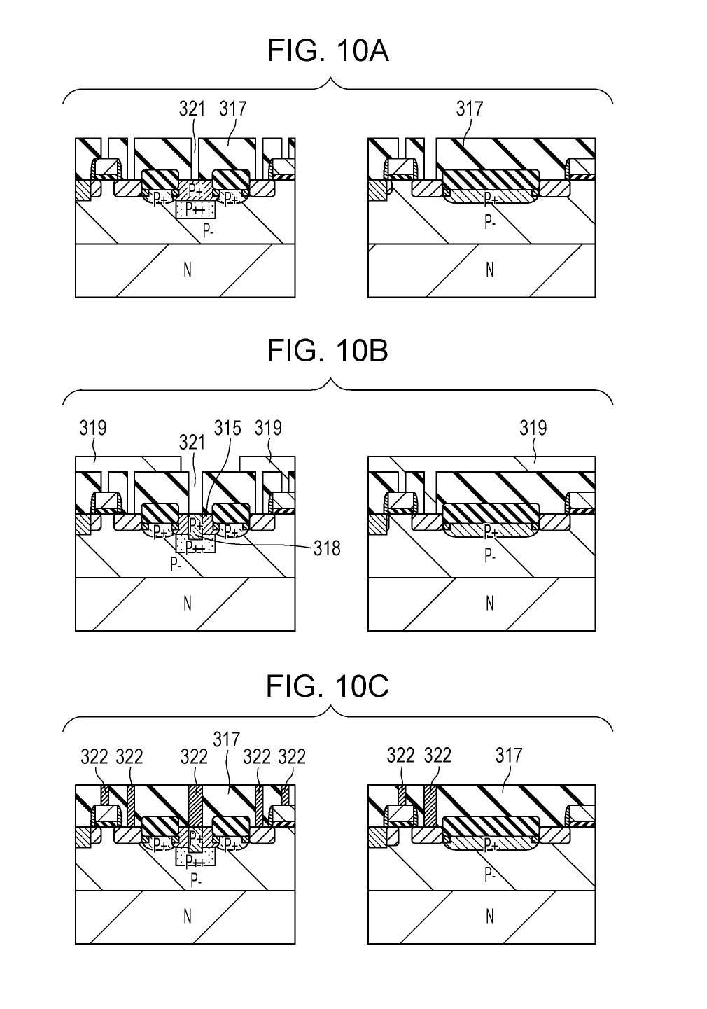

Next, as illustrated in FIG. 10A, a plurality of contact holes including a contact hole 321 corresponding to the well contact region 110 are formed in the interlayer insulation film 317 of the intermediate L. The plurality of contact holes are formed in the regions corresponding to the regions which become the gate electrode, the source region and the drain region of each transistor, the FD, and the well contact region 110 (“intermediate M”).

Next, as illustrated in FIG. 10B, a mask 319 which covers the contact holes except for the contact hole 321 is formed. Then P-type ion implantation is conducted using the contact hole 321 disposed in the region corresponding to the well contact region 110 as a mask.

Therefore, the P-type semiconductor region 318 is formed at a part of the P-type semiconductor region 315. The P-type semiconductor region 318 may be formed also at a part of the P-type semiconductor region 314. The well contact region 110 is constituted by the P-type semiconductor regions 314, 315, and 318. Impurity concentration of the P-type semiconductor region 318 is higher than those of the P-type semiconductor regions 314, 315, and 316 (“intermediate L”).

Next, as illustrated in FIG. 10C, an electric conductor is embedded in each contact hole to form a contact plug 322 (“intermediate N”). The contact hole 321 disposed in the region corresponding to the well contact region 110 may be covered before this process. In that case, N-type ion implantation may be conducted using a mask with openings in the regions corresponding to the contact holes corresponding to the gate electrode, the source region, and the drain region of each transistor.

Then, after forming a required number of wiring layers by a well-known wiring process, a passivation film, a color filter, and a microlens are formed to complete an image pickup apparatus.

According to the manufacturing method described above, in a case where some of a plurality of pixels 101 have the well contact region 110 and others do not, variation in ion implantation when N-type ion implantation is conducted at an oblique angle to the normal line of the principal surface can be reduced. Therefore, variation in impurity concentration distribution of the semiconductor region which constitutes the input node of the amplifying transistor 105 can be reduced. Therefore, variation in capacitance of the input node of the amplifying transistor can be reduced.

Although the source region of the reset transistor 106 and the FD 104 are disposed in different active regions in the present embodiment, this configuration is not restrictive. The source region of the reset transistor 106 and the FD 104 may be disposed in the same active region, and may be constituted by the same semiconductor region (“first semiconductor region”).

In the present embodiment, the regions adjacent to the well contact region 110 via the element isolation region 306 are the FD 104 and the source region of the reset transistor 106. However, this configuration is not restrictive: for example, the same effect can be provided if a semiconductor region including a switch that can switch capacitance of the input node is disposed in the region adjacent to the well contact region 110 via the element isolation region 306.

### Second Embodiment

The present embodiment differs from the first embodiment in the position at which the well contact region 110 is disposed in the pixel unit 100.

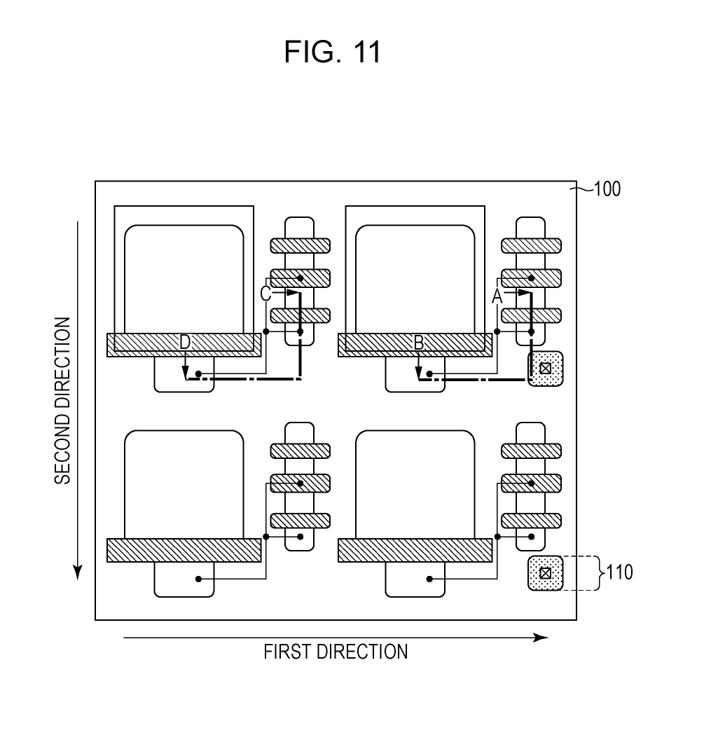

The present embodiment differs from the first embodiment in that, as illustrated in FIG. 11, a distance between the well contact region 110 and the source region of the reset transistor 106 is shorter than a distance between the well contact region 110 and the FD 104.

In the present embodiment, a process of forming the source region of the reset transistor 106 and the process of forming the FD 104 are conducted separately. When forming the source region of the reset transistor 106, the region which becomes the well contact region 110 is not shielded. When forming the FD 104, the region which becomes the well contact region 110 is shielded.

In a semiconductor region in which a distance to the well contact region 110 is shorter, variation in impurity concentration when the well contact region 110 is shielded with a mask is larger. Therefore, according to the present embodiment, variation in impurity concentration when forming the source region of the reset transistor 106 with shorter distance can be reduced.

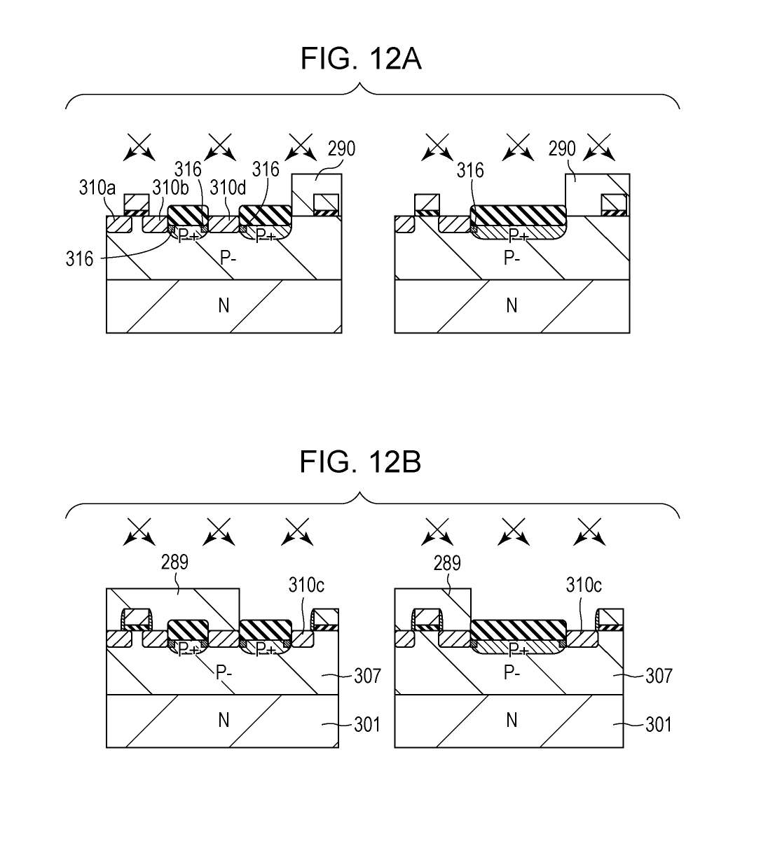

A method for manufacturing the image pickup apparatus along lines A-B and C-D of FIG. 11 is described with reference to FIGS. 12A and 12B. Processes different from those of the first embodiment are described.

FIG. 12A illustrates a subsequent state of the intermediate F of FIG. 7C of the first embodiment. The region in which the FD 104 is formed is covered with a mask 290, and N-type impurity implantation is conducted in the regions which become the source region and the drain region of each transistor, whereby the N-type semiconductor regions 310a, 310b, and 310d are formed (“intermediate P”). Ion implantation is conducted from an oblique angle to the normal line of the principal surface of the semiconductor substrate in the same manner as the process of FIG. 8A.

Specifically, rotational ion implantation is conducted at an angle inclined from 20 to 70 degrees to the normal line of the principal surface. The dosage at this time is 2.5×10¹² atoms/cm²≦D1≦2.5×10¹⁴ atoms/cm²

The ion implantation is conducted with the photoelectric conversion unit 102, the gate of the transfer transistor 103, and the FD 104 being covered using the mask 290 formed by, for example, photoresist.

The mask 290 has openings corresponding to a region which becomes the well contact region 110, and a region which becomes the source region of the reset transistor 106. Further, the mask 290 has an opening corresponding to the element isolation region 306 disposed between the region which becomes the well contact region 110 and a region which becomes the source region of the reset transistor 106.

The source region of the reset transistor 106 can be formed in this process. An opening corresponding to the element isolation region 306 disposed between the region which becomes the FD 104 and the region which becomes the well contact region 110 may be formed.

Since the mask 290 used in this process is disposed to cover the region which becomes the FD 104, N-type impurity implantation is not conducted in the region which becomes the FD 104. Since the mask 290 is disposed not to cover the region which becomes the well contact region 110, N-type ion implantation is conducted in the region which becomes the well contact region 110.

Next, in FIG. 12B, the source region and the drain region of other transistors (i.e., an amplifying transistor and a selection transistor) of the pixel and the region which becomes the well contact region 110 are shielded to the intermediate P. Further, the source region of the reset transistor 106 is shielded. A mask 289 having openings in the element isolation region 306 disposed between the region which becomes the well contact region 110 and the FD 104, and in the region which becomes FD 104 is formed. Then N-type impurity implantation is conducted using the mask 289.

Then N-type impurity is implanted in the region in which FD 104 is formed and the N-type semiconductor region 310c is formed (“intermediate Q”). Subsequent processes are the same as those of the first embodiment.

According to the present embodiment, ion implantation is conducted also in the region which becomes the well contact region 110 when forming a semiconductor region relatively closer to the well contact region 110 among the semiconductor regions which constitute the input node of the amplifying transistor.

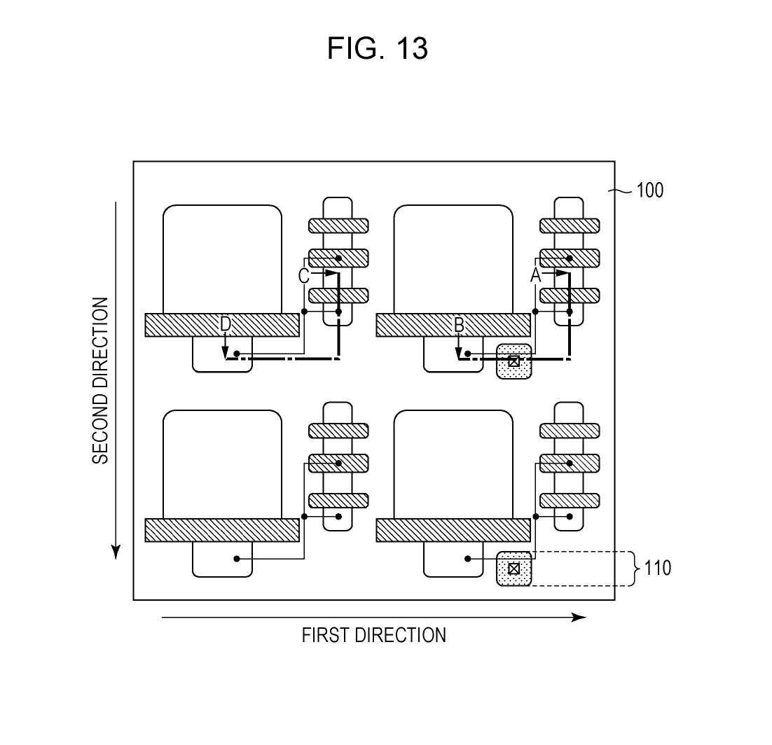

The present embodiment is applicable also to a case where, as illustrated in FIG. 13, a distance between the FD 104 and the well contact region 110 is shorter than a distance between the source region of the reset transistor 106 and the well contact region 110. In this case, in the process of forming the FD 104, openings corresponding to the region which becomes the well contact region 110 and the region which becomes the FD 104 are formed in the mask. Further, an opening corresponding to the element isolation region 306 disposed between the region which becomes the well contact region 110 and the region which becomes the FD 104 is formed.

In the process of forming the source region of the reset transistor 106, the region which becomes the well contact region 110 is shielded. Further, a mask 289 having openings in the element isolation region 306 disposed between the region which becomes the well contact region 110 and the region which becomes the source region of the reset transistor 106, and in the region which becomes the source region of the reset transistor 106 is formed.

According also to the present embodiment, it is possible to reduce variation in impurity concentration in the semiconductor region which constitutes the input node of the amplifying transistor 105 between the pixel in which the well contact region 110 is disposed and the pixel in which no well contact region 110 is disposed. Therefore, it is possible to reduce variation in capacitance of the input node of the amplifying transistor.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-006070, filed Jan. 15, 2015 which is hereby incorporated by reference herein in its entirety.

What is claimed is:

1. A method for manufacturing an image pickup apparatus which includes a plurality of pixels, in a well of a first conductivity type, each of which has a photoelectric conversion unit, floating diffusion which holds charge generated in the photoelectric conversion unit, an amplifying transistor electrically connected to the floating diffusion, and a reset transistor which resets a potential of an input node of the amplifying transistor, wherein
some of the plurality of pixels have a well contact region connected to a conductor which supplies a predetermined voltage to the well and others do not,
each of the plurality of pixels has a first semiconductor region of a second conductive type which constitutes a source region of the reset transistor and the floating diffusion in the well of the first conductivity type, and an element isolation region is disposed on a principal surface of a semiconductor substrate, and
a second semiconductor region of a first conductive type which becomes the well contact region is disposed at a position adjacent to the first semiconductor region via the element isolation region in a pixel which has the well contact region, the method comprising:
a first process in which a first mask having openings in a region which becomes the first semiconductor region, the element isolation region disposed between a region which becomes the first semiconductor region and a region which becomes the second semiconductor region, and the region which becomes the second semiconductor region is disposed, and
ion implantation of a second conductive type is conducted at an oblique angle to a normal line of the principal surface using the first mask to form the first semiconductor region in the region which becomes the first semiconductor region; and
a second process in which a second mask which covers the region which becomes the first semiconductor region and has an opening in the region which becomes the second semiconductor region is disposed, and the second semiconductor region is formed in the region which becomes the second semiconductor region by conducting ion implantation of the first conductive type using the second mask.

2. The method for manufacturing an image pickup apparatus according to claim 1, wherein the first process is conducted before the second process.

3. The method for manufacturing an image pickup apparatus according to claim 1, wherein each of the plurality of pixels has
a transfer transistor configured to transmit the charge of the photoelectric conversion unit to the input node of the amplifying transistor, and
a process of forming a gate electrode of the transfer transistor and a gate electrode of the reset transistor on the principal surface, is included before the first process and the second process.

4. The method for manufacturing an image pickup apparatus according to claim 1, wherein the floating diffusion and the source region of the reset transistor are disposed in different active regions.

5. The method for manufacturing an image pickup apparatus according to claim 1, wherein, in the first process, the source region of the reset transistor and the floating diffusion are formed in the same ion implantation process using the first mask.

6. The method for manufacturing an image pickup apparatus according to claim 5, wherein, in the first process, one of the source region of the reset transistor and the floating diffusion closer to the second semiconductor region is formed using the first mask, and one of the source region of the reset transistor and the floating diffusion farther from the second semiconductor region is formed using a mask in which a portion corresponding to a region in which the second semiconductor region is formed in the second process is shielded.

7. The method for manufacturing an image pickup apparatus according to claim 1, wherein the first semiconductor region and the second semiconductor region are disposed in different active regions separated by the element isolation region.

8. The method for manufacturing an image pickup apparatus according to claim 1, wherein the first conductive impurity implantation in the second process is conducted in parallel with a normal line of the principal surface.
